(19) United States
(12) Patent Application Publication
(10) Pub. No.: US 2012/0244663 A1
(43) Pub. Date: Sep. 27, 2012

(54) SEMICONDUCTOR DEVICE CHIP MOUNTING METHOD

(75) Inventor: Takashi Mori, Ota-Ku (JP)

(73) Assignee: DISCO CORPORATION, Tokyo (JP)

(21) Appl. No.: 13/423,454

(22) Filed: Mar. 19, 2012

(30) Foreign Application Priority Data
Mar. 25, 2011 (JP) 2011-067621

(51) Int. Cl. H01L 21/78

(52) U.S. Cl. 438/113; 257/E21.599

(57) ABSTRACT

A semiconductor device chip has a plurality of projecting electrodes mounted on a wiring board or wafer having electrodes respectively corresponding to the projecting electrodes of the semiconductor device chip. An insulator is applied to the front side of the semiconductor device wafer where the projecting electrodes are formed, to fill any spaces between adjacent electrodes with the insulator. The front side of the wafer covered with the insulator is planarized to expose the end surfaces of the projecting electrodes, and the wafer is divided along division lines to obtain a plurality of individual semiconductor device chips. Each chip is mounted on the wiring board or the wafer with an anisotropic conductor interposed between the projecting electrodes of each chip and the electrodes of the wiring board or the wafer to thereby respectively connect the projecting electrodes and the electrodes through the anisotropic conductor.

### BACKGROUND OF THE INVENTION

1. Field of the Invention

The present invention relates to a semiconductor device chip mounting method of mounting a semiconductor device chip with bumps on a wiring board or wafer having electrodes and electrically connecting the bumps of the semiconductor device chip to the electrodes of the wiring board or wafer.

2. Description of the Related Art

As a technique for realizing the miniaturization of a semiconductor device chip, there has recently been put into practical use a mounting technique called flip chip bonding such that a plurality of projecting electrodes called bumps are formed on the device surface of the chip and these bumps are respectively directly bonded to electrodes formed on a wiring board (see Japanese Patent Laid-open No. 2001-237278, for example). In the case of mounting a semiconductor device chip with bumps on a wiring board or wafer having electrodes and bonding the bumps of the semiconductor device chip to the electrodes of the wiring board or wafer or in the case of connecting semiconductor wafers with bumps to each other, an anisotropic conductive material (anisotropic conductor) such as an anisotropic conductive film (ACF) or an anisotropic conductive paste (ACP) is used.

The anisotropic conductive film is obtained by dispersing conductive metal particles in a thermosetting epoxy resin and forming the resin into a film. Each conductive metal particle is a spherical member formed of nickel, gold, etc. and has a diameter of several micrometers. Each conductive metal particle has a multilayer structure mainly composed of a nickel layer as an inner layer, a gold plating layer formed on the nickel layer, and an insulating layer as an outermost layer. On the other hand, the anisotropic conductive paste is obtained by forming the above resin containing the conductive metal particles into a paste. For example, after mounting a semiconductor device chip with bumps through an anisotropic conductive material on a wiring board having electrodes, heat and pressure are applied to the semiconductor device chip by using a pad or the like. As a result, the conductive metal particles dispersed in the anisotropic conductive material present between the bumps and the electrodes are brought into pressure contact with each other to thereby form a conducting path between the bumps and the electrodes.

As described above, each conductive metal particle has an insulating layer as an outermost layer, so that the conductive metal particles present between the bumps and not pressurized still retain the insulating layers, thereby maintaining the insulation between the bumps. Thus, anisotropy is exhibited so that conductivity is maintained in a direction perpendicular to the device surface of the chip and insulation is maintained in a direction parallel to the device surface of the chip. Accordingly, even when the spacing between the bumps is small, the anisotropic conductive material has a merit such that the semiconductor device chip with the bumps can be mounted without a short circuit between the bumps.

### SUMMARY OF THE INVENTION

With a reduction in size and thickness and an advance in functionality of recent electronic equipment, the pitch of the bumps on the semiconductor device chip is reduced. Accordingly, there is a possibility that a conducting path may be formed between the bumps at the time of filling the spacing between the bumps with the anisotropic conductive material.

It is therefore an object of the present invention to provide a semiconductor device chip mounting method using an anisotropic conductive material which can eliminate the possibility of formation of a conducting path between the bumps.

In accordance with a first aspect of the present invention, there is provided a semiconductor device chip mounting method of mounting a semiconductor device chip having a plurality of projecting electrodes on a wiring board or wafer having electrodes respectively corresponding to the projecting electrodes of the semiconductor device chip, the semiconductor device chip mounting method including a preparing step of preparing a semiconductor device wafer having a plurality of crossing division lines for partitioning a plurality of regions where a plurality of semiconductor devices are respectively formed, each semiconductor device having the projecting electrodes; an insulator applying step of applying an insulator to the front side of the semiconductor device wafer where the projecting electrodes are formed to fill the spacing between any adjacent ones of the projecting electrodes with the insulator after performing the preparing step; a projecting electrode end exposing step of planarizing the front side of the semiconductor device wafer covered with the insulator to expose the end surfaces of the projecting electrodes after performing the insulator applying step; a dividing step of dividing the semiconductor device wafer along the division lines to obtain a plurality of individual semiconductor device chips respectively corresponding to the semiconductor devices after performing the projecting electrode end exposing step; and a mounting step of mounting each semiconductor device chip on the wiring board or the wafer with an anisotropic conductor interposed between the projecting electrodes of each semiconductor device chip and the electrodes of the wiring board or the wafer to thereby respectively connect the projecting electrodes and the electrodes through the anisotropic conductor after performing the dividing step.

In accordance with a second aspect of the present invention, there is provided a semiconductor device chip mounting method of mounting a semiconductor device chip having a plurality of projecting electrodes on a wiring board or wafer having electrodes respectively corresponding to the projecting electrodes of the semiconductor device chip, the semiconductor device chip mounting method including an insulator applying step of applying an insulator to the front side of the semiconductor device chip where the projecting electrodes are formed to fill the spacing between any adjacent ones of the projecting electrodes with the insulator; a projecting electrode end exposing step of planarizing the front side of the semiconductor device chip covered with the insulator to expose the end surfaces of the projecting electrodes after performing the insulator applying step; and a mounting step of mounting the semiconductor device chip on the wiring board or the wafer with an anisotropic conductor interposed between the projecting electrodes of the semiconductor device chip and the electrodes of the wiring board or the wafer to thereby respectively connect the projecting electrodes and the electrodes through the anisotropic conductor after performing the projecting electrode end exposing step.

Preferably, the semiconductor device chip mounting method according to the second aspect of the present invention further includes an attaching step of attaching a plurality of semiconductor device chips to an adhesive tape after performing the insulator applying step, whereby the projecting electrode end exposing step is performed in the condition that the plurality of semiconductor device chips are attached to the adhesive tape.

According to the mounting method of the present invention, the spacing between the adjacent projecting electrodes is filled with the insulator, and the semiconductor device chip is next mounted through the anisotropic conductor on the wiring board or wafer. Accordingly, no conducting path is formed between the adjacent projecting electrodes. Further, the spacing between the adjacent projecting electrodes is filled with the insulator, and the insulator covering all of the projecting electrodes is planarized to uniform the heights of the projecting electrodes. Accordingly, faulty connection due to variations in height between the projecting electrodes can be prevented.

In the projecting electrode end exposing step, the insulator is planarized to expose the end surfaces of the projecting electrodes, so that an oxide film having a thickness of several angstroms is undesirably formed on the end surfaces of the projecting electrodes exposed to the atmosphere. To remove the oxide film, any processing such as dry etching or wet etching must be performed. However, there is a problem that it is very difficult to etch only the end surfaces of the projecting electrodes. In this respect, the semiconductor device chip is mounted through the anisotropic conductor on the wiring board or wafer according to the present invention. Accordingly, in mounting the semiconductor device chip, the conductive metal particles in the anisotropic conductor can penetrate the oxide film to form a conducting path, thereby eliminating the need for removal of the oxide film.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a flowchart showing a semiconductor device chip mounting method according to a first preferred embodiment of the present invention;

FIG. 2 is a perspective view of a semiconductor device wafer having a plurality of semiconductor devices with bumps;

FIG. 3 is a schematic side view of the semiconductor device wafer;

FIG. 4 is a partially sectional side view showing an insulator applying step;

FIG. 5 is a partially sectional side view showing a projecting electrode end exposing step;

FIG. 6 is a partially sectional side view of the semiconductor device wafer in the condition after performing the projecting electrode end exposing step;

FIG. 7 is a partially sectional side view showing a back grinding step;

FIG. 8 is a partially sectional side view showing a transferring step of transferring the semiconductor device wafer from a protective tape to a dicing tape;

FIG. 9 is a partially sectional side view showing a dividing step of dividing the semiconductor device wafer into individual semiconductor device chips;

FIG. 10A is a side view for illustrating a mounting step of mounting each semiconductor device chip on a wiring board;

FIG. 10B is a side view showing the condition that the semiconductor device chip is mounted on the wiring board;

FIG. 11 is a flowchart showing a semiconductor device chip mounting method according to a second preferred embodiment of the present invention;

FIG. 12 is a partially sectional side view showing a projecting electrode end exposing step in the second preferred embodiment; and

FIG. 13 is a partially sectional side view of a plurality of semiconductor device chips supported through an adhesive tape to an annular frame in the condition after performing the projecting electrode end exposing step.

### DETAILED DESCRIPTION OF THE PREFERRED EMBODIMENTS

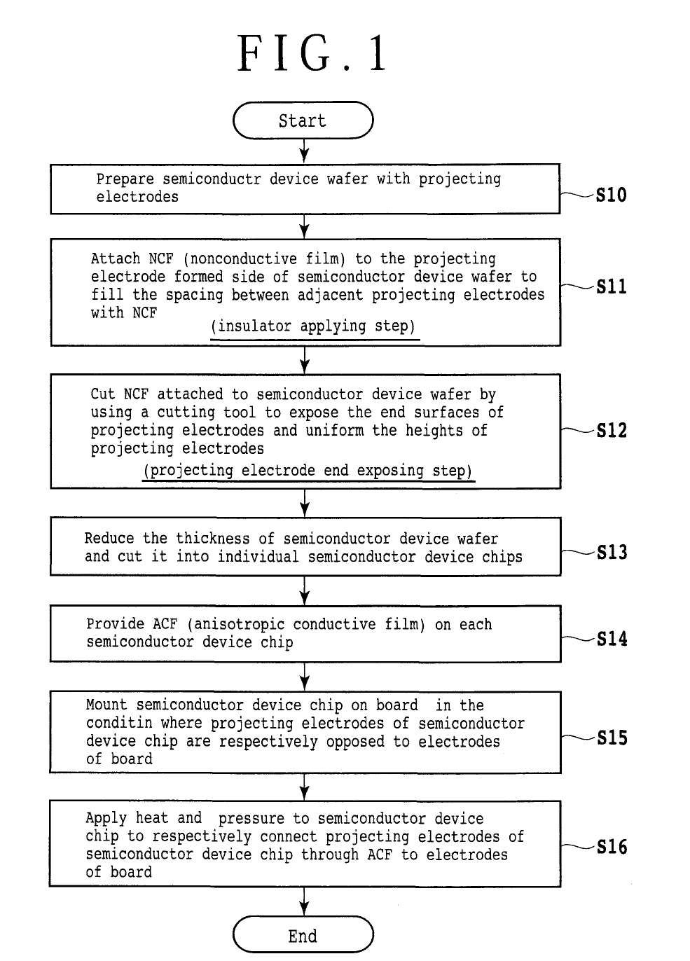

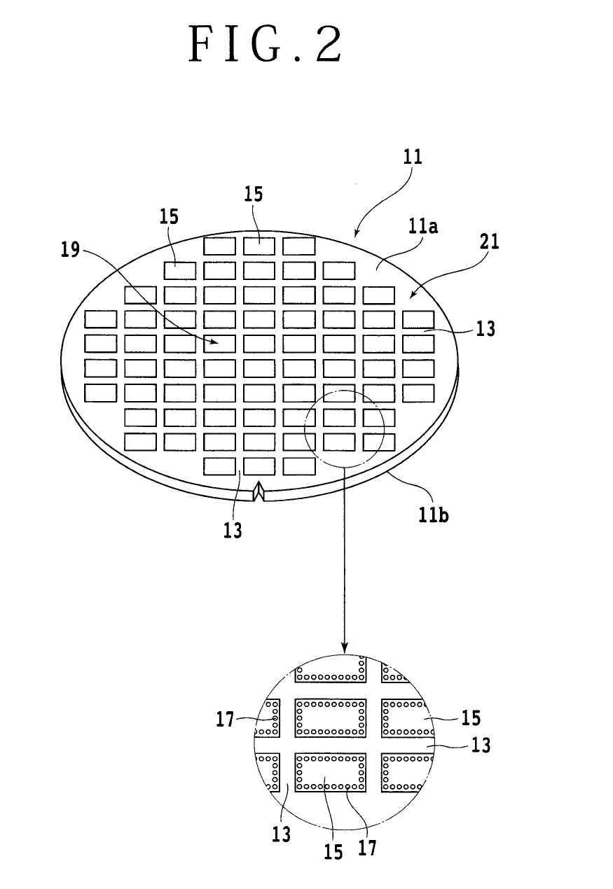

Some preferred embodiments of the present invention will now be described in detail with reference to the drawings. In a semiconductor device chip mounting method according to a first preferred embodiment of the present invention, a preparing step as step S10 of the flowchart shown in FIG. 1 is first performed to prepare a semiconductor device wafer 11 with projecting electrodes (bumps) shown in FIG. 2. As shown in FIG. 2, the semiconductor device wafer 11 has a front side 11a and a back side 11b. A plurality of crossing division lines (streets) 13 are formed on the front side 11a to thereby partition a plurality of rectangular regions where a plurality of semiconductor devices 15 are respectively formed.

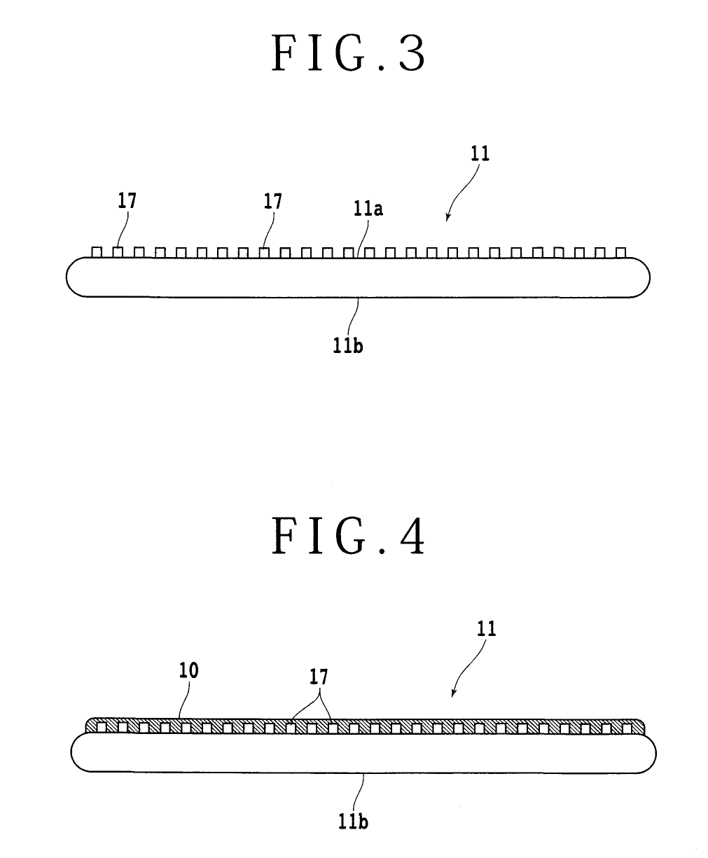

As shown in an enlarged (encircled) part of FIG. 2, a plurality of projecting bumps 17 are formed on each semiconductor device 15 along the four edges thereof. Thus, the bumps 17 are formed along the four edges of each semiconductor device 15. Accordingly, the semiconductor device wafer 11 has a bump formed area 19 where the bumps 17 are formed and a bump unformed area 21 where no bumps are formed as surrounding the bump formed area 19. FIG. 3 shows a schematic side view of the semiconductor device wafer 11.

After performing the preparing step mentioned above, an insulator applying step as step S11 shown in FIG. 1 is performed in such a manner that a nonconductive film (NCF) 10 is attached to the front side 11a (projecting electrode formed side where the bumps 17 are formed) of the semiconductor device wafer 11 as shown in FIG. 4 to fill the spacing between any adjacent ones of the bumps 17 with the nonconductive film 10. The NCF 10 is formed of epoxy resin, for example. The NCF 10 may be replaced by a nonconductive paste (NCP).

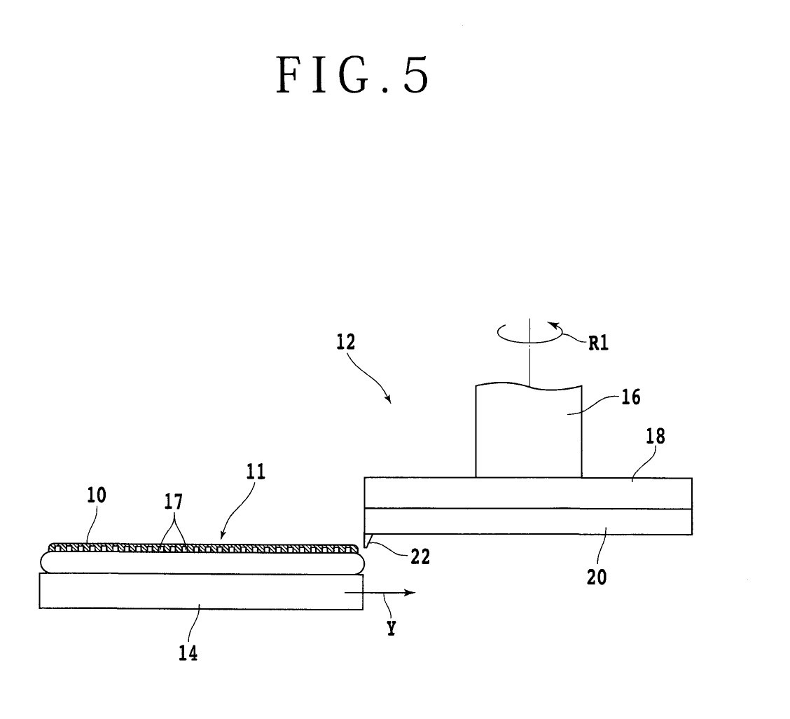

After performing the insulator applying step mentioned above, a projecting electrode end exposing step as step S12 shown in FIG. 1 is performed in such a manner that the NCF 10 attached to the semiconductor device wafer 11 is cut by a cutting tool to expose the end surfaces of the bumps 17 and uniform the heights of the bumps 17. Referring to FIG. 5, there is shown a partially sectional side view in the condition where the projecting electrode end exposing step is being performed by using a single point tool cutting apparatus 12. The single point tool cutting apparatus 12 shown in FIG. 5 includes a chuck table 14 for holding the semiconductor device wafer 11 covered with the NCF 10 under suction.

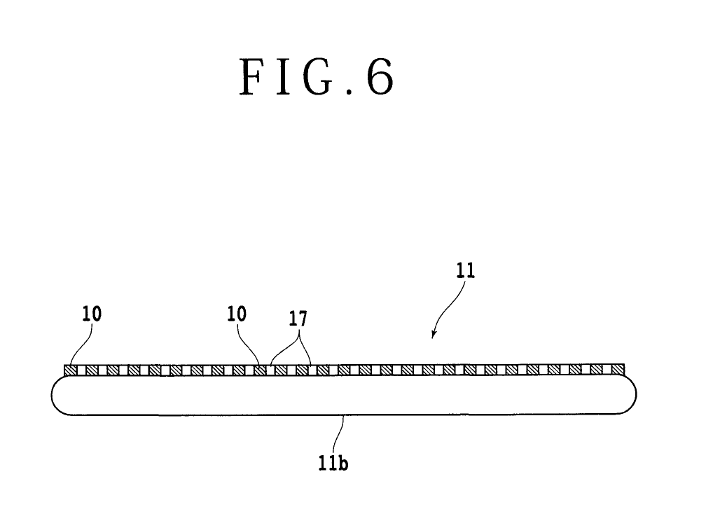

The single point tool cutting apparatus 12 further includes a spindle 16, a mounter 18 fixed to the lower end of the spindle 16, and a cutting wheel 20 detachably fixed to the lower surface of the mounter 18. The cutting wheel 20 has a single point tool 22 on the lower side. When the cutting wheel 20 is rotated in the direction shown by an arrow R1 in FIG. 5 and the chuck table 14 is fed at a low speed in the direction shown by an arrow Y in FIG. 5, the nonconductive film (NCF) 10 covering the bumps 17 is cut to be planarized and the end surfaces of the bumps 17 are exposed. FIG. 6 shows a partially sectional side view in the condition after performing the projecting electrode end exposing step. As apparent from FIG. 6, the end surfaces of the bumps 17 are exposed and the spacing between any adjacent ones of the bumps 17 is filled with the NCF 10.

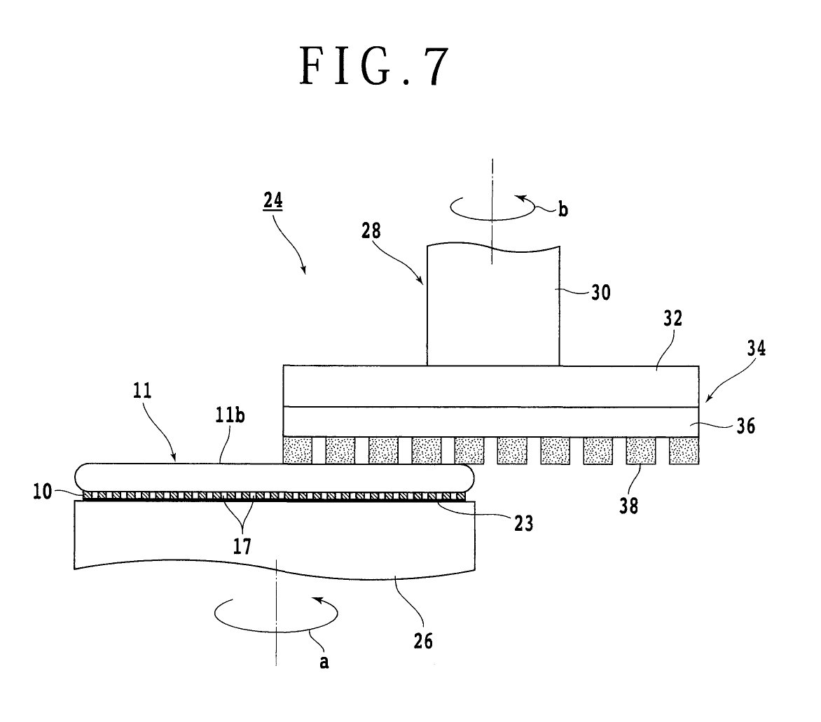

After performing the projecting electrode end exposing step, a back grinding step of grinding the back side 11b of the semiconductor device wafer 11 to reduce the thickness thereof and a dividing step of cutting the semiconductor device wafer 11 into individual semiconductor device chips are performed as step S13 shown in FIG. 1. The back grinding step is performed by using a grinding apparatus 24 shown in FIG. 7. As shown in FIG. 7, the grinding apparatus 24 includes a chuck table 26 for holding the semiconductor device wafer 11 under suction in the condition where a protective tape 23 is attached to the end surfaces of the bumps 17 and the protective tape 23 comes into contact with the upper surface of the chuck table 26. Thus, the semiconductor device wafer 11 is held through the protective tape 23 on the chuck table 26 under suction in the condition where the back side 11b of the semiconductor device wafer 11 is exposed, or oriented upward.

The grinding apparatus 24 further includes a grinding unit 28 for grinding the back side 11b of the semiconductor device wafer 11 held on the chuck table 26. The grinding unit 28 includes a spindle 30, a wheel mount 32 fixed to the lower end of the spindle 30, and a grinding wheel 34 detachably mounted on the lower surface of the wheel mount 32. The grinding wheel 34 includes an annular base 36 and a plurality of abrasive members 38 mounted on the lower surface of the annular base 36 so as to be arranged at intervals along the outer circumference thereof. The chuck table 26 holding the semiconductor device wafer 11 is rotated at 300 rpm, for example, in the direction shown by an arrow “a” in FIG. 7 and the grinding wheel 34 is rotated at 6000 rpm, for example, in the direction shown by an arrow “b” in FIG. 7. In this condition, a grinding unit feeding mechanism (not shown) included in the grinding apparatus 24 is driven to bring the abrasive members 38 of the grinding wheel 34 into contact with the back side 11b of the semiconductor device wafer 11 as shown in FIG. 7. Thereafter, the grinding wheel 34 is further fed downward by a predetermined amount at a predetermined feed speed, thereby grinding the back side 11b of the semiconductor device wafer 11 to reduce the thickness thereof to 70 μm, for example.

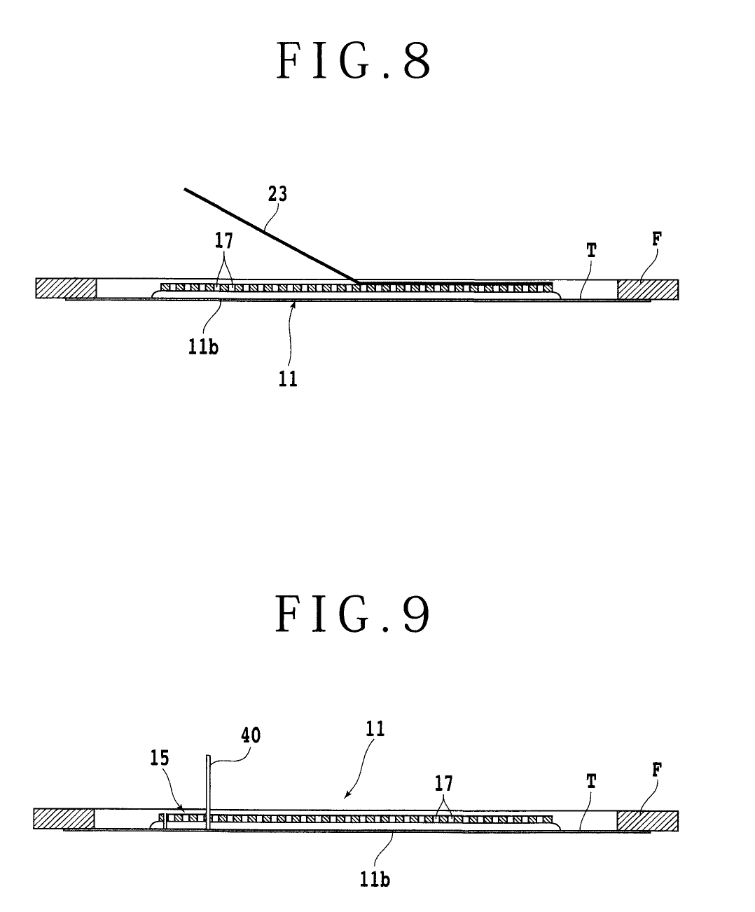

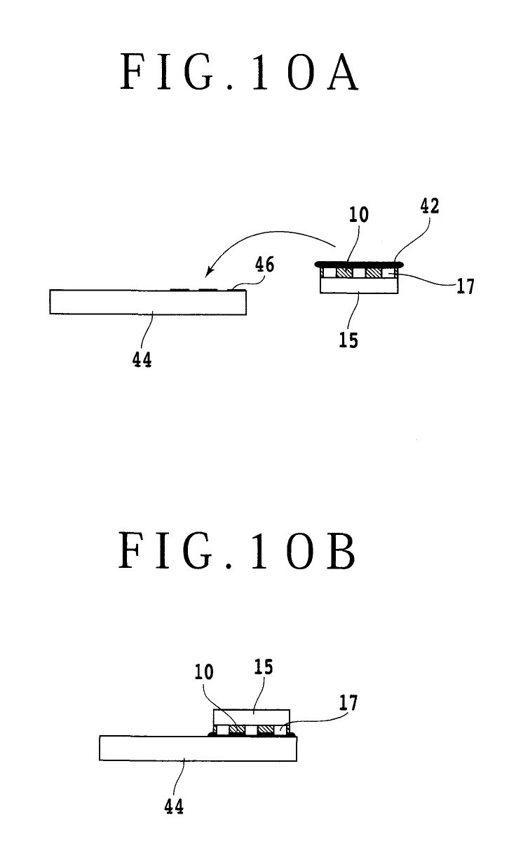

After performing the back grinding step mentioned above, a transferring step is performed to transfer the semiconductor device wafer 11 from the protective tape 23 to a dicing tape T as shown in FIG. 8. In this transferring step, the back side 11b of the semiconductor device wafer 11 reduced in thickness is attached to the dicing tape T supported at its outer circumferential portion to an annular frame F, and the protective tape 23 is next peeled off from the bumps 17. Thereafter, the dividing step is performed in such a manner that the semiconductor device wafer 11 is held through the dicing tape T on a chuck table of a cutting apparatus (not shown) under suction and cut along the division lines 13 by using a cutting blade 40 as shown in FIG. 9 to obtain the individual semiconductor device chips 15.

After performing the dividing step mentioned above, a mounting step as steps S14 to S16 shown in FIG. 1 is performed as shown in FIGS. 10A and 10B. In this mounting step, an anisotropic conductive film (ACF) 42 is first provided on the bumps 17 of each semiconductor device chip 15 as shown in FIG. 10A (step S14). The ACF 42 may be replaced by an anisotropic conductive paste (ACP). Thereafter, as shown in FIG. 10B, the semiconductor device chip 15 is mounted on a wiring board 44 in the condition where the bumps 17 of the semiconductor device chip 15 are respectively opposed to electrodes 46 formed on the wiring board 44 with the ACF 42 interposed therebetween (step S15). While the ACF 42 is provided on the bumps 17 of each semiconductor device chip 15 as shown in FIG. 10A, the ACF 42 may be provided on the electrodes 46 of the wiring board 44.

Thereafter, heat and pressure are applied to the semiconductor device chip 15 by using a heater and an elastic pad such as a rubber member (step S16). As a result, the conductive metal particles dispersed in the ACF 42 present between the bumps 17 and the electrodes 46 come into pressure contact with each other to form a conducting path for connecting the bumps 17 of the semiconductor device chip 15 and the electrodes 46 of the wiring board 44. The nonconductive film (NCF) 10 is present between any adjacent ones of the bumps 17. Accordingly, although the spacing between the adjacent bumps 17 is small, no short circuit occurs between the adjacent bumps 17 in applying heat and pressure to the semiconductor device chip 15, so that the semiconductor device chip 15 can be mounted on the wiring board 44 without a short circuit between the adjacent bumps 17.

While the bumps 17 of the semiconductor device chip 15 are connected through the ACF 42 to the electrodes 46 of the wiring board 44 in this preferred embodiment, the present invention is not limited to this preferred embodiment, but may be applied to the case that the bumps 17 of the semiconductor device chip 15 are connected through the ACF 42 to electrodes of a wafer.

Further, while the mounting method of the present invention is applied to the semiconductor device wafer in this preferred embodiment, the present invention is not limited to this preferred embodiment, but may be applied to the case that the bumps of each of a plurality of semiconductor device chips obtained by dividing a semiconductor device wafer are connected to electrodes of a wiring board or wafer.

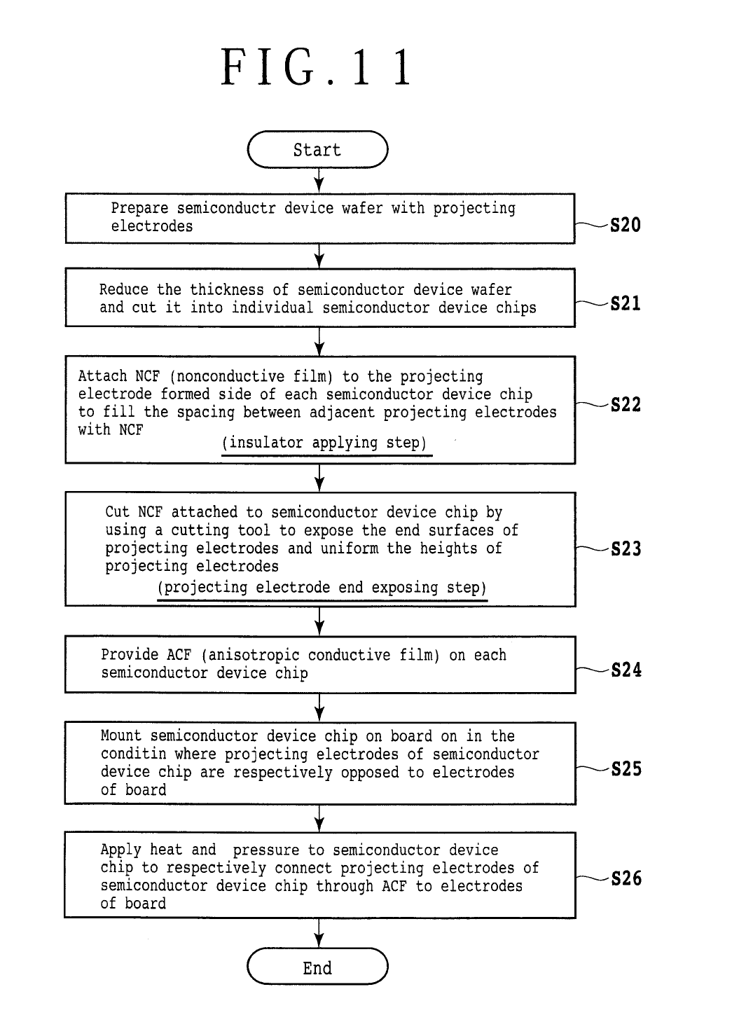

This latter case will now be described as a second preferred embodiment with reference to FIGS. 11 to 13. In the second preferred embodiment, step S20 of the flowchart shown in FIG. 11 is first performed to prepare a semiconductor device wafer 11 with projecting electrodes (bumps). Thereafter, step S21 shown in FIG. 11 is performed to grind the back side of the semiconductor device wafer 11 by using a grinding apparatus, thereby reducing the thickness of the wafer 11 and next cut the semiconductor device wafer 11 into the individual semiconductor device chips 15 by using a cutting apparatus.

Thereafter, step S22 shown in FIG. 11 is performed as an insulator applying step. In this insulator applying step, a nonconductive film (NCF) 10 is attached to the front side (projecting electrode formed side where the bumps 17 are formed) of each semiconductor device chip 15 to fill the spacing between any adjacent ones of the bumps 17 with the nonconductive film 10. The NCF 10 is formed of epoxy resin, for example. The NCF 10 may be replaced by a nonconductive paste (NCP).

After performing the insulator applying step mentioned above, step S23 shown in FIG. 11 is performed as a projecting electrode end exposing step. In this projecting electrode end exposing step, the plural semiconductor device chips 15 each covered with the NCF 10 are attached to an adhesive tape T supported at its outer circumferential portion to an annular frame F.

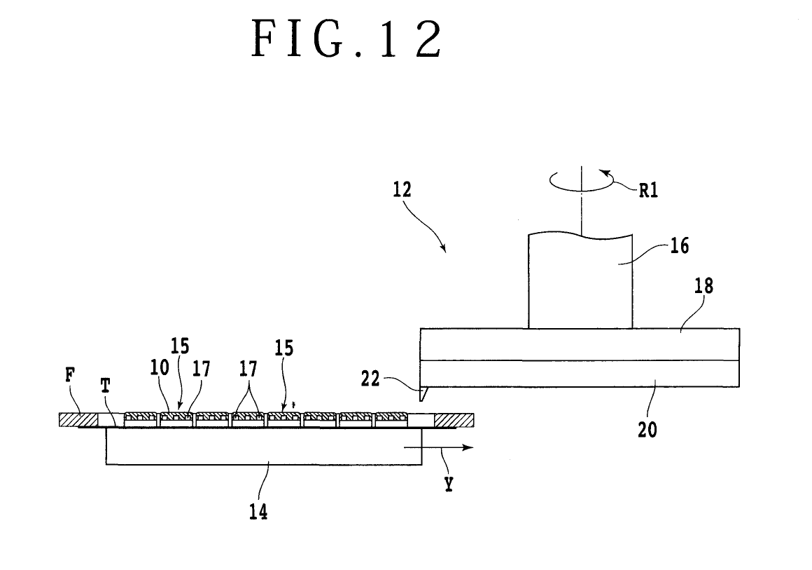

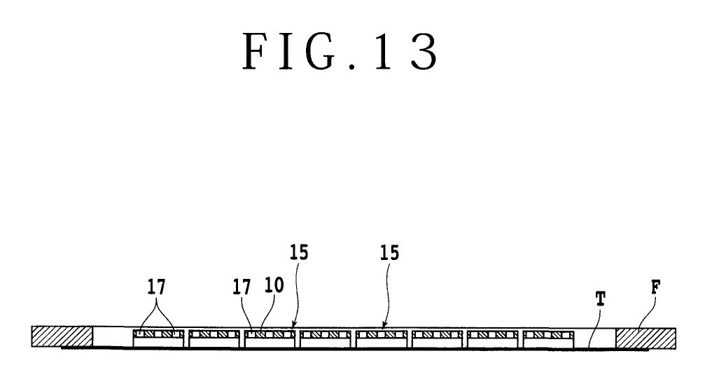

Thereafter, as shown in FIG. 12, the plural semiconductor device chips 15 each covered with the NCF 10 are held under suction through the adhesive tape T on the chuck table 14 of the single point tool cutting apparatus 12. When the cutting wheel 20 is rotated in the direction shown by an arrow R1 in FIG. 12 and the chuck table 14 is fed at a low speed in the direction shown by an arrow Y in FIG. 12, the nonconductive film (NCF) 10 covering the bumps 17 of each semiconductor device chip 15 is cut to be planarized and the end surfaces of the bumps 17 are exposed. FIG. 13 shows a partially sectional side view in the condition after performing the projecting electrode end exposing step. As apparent from FIG. 13, the end surfaces of the bumps 17 of each semiconductor device chip 15 are exposed and the spacing between any adjacent ones of the bumps 17 is filled with the NCF 10.

After performing the projecting electrode end exposing step, each semiconductor device chip 15 is peeled off from the adhesive tape T, and an anisotropic conductive film (ACF) is provided on each semiconductor device chip 15 (step S24). The steps S24 to S26 shown in FIG. 11 are respectively similar to the steps S14 to S16 shown in FIG. 1, and the detailed description thereof will be omitted herein because it has been described above with reference to FIGS. 10A and 10B.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A semiconductor device chip mounting method of mounting a semiconductor device chip having a plurality of projecting electrodes on a wiring board or wafer having electrodes respectively corresponding to said projecting electrodes of said semiconductor device chip, said semiconductor device chip mounting method comprising:
a preparing step of preparing a semiconductor device wafer having a plurality of crossing division lines for partitioning a plurality of regions where a plurality of semiconductor devices are respectively formed, each semiconductor device having said projecting electrodes;
an insulator applying step of applying an insulator to a front side of said semiconductor device wafer where said projecting electrodes are formed to fill a spacing between any adjacent ones of said projecting electrodes with said insulator after performing said preparing step;
a projecting electrode end exposing step of planarizing the front side of said semiconductor device wafer covered with said insulator to expose end surfaces of said projecting electrodes after performing said insulator applying step;
a dividing step of dividing said semiconductor device wafer along said division lines to obtain a plurality of individual semiconductor device chips respectively corresponding to said semiconductor devices after performing said projecting electrode end exposing step; and
a mounting step of mounting each semiconductor device chip on said wiring board or said wafer with an anisotropic conductor interposed between said projecting electrodes of each semiconductor device chip and said electrodes of said wiring board or said wafer to thereby respectively connect said projecting electrodes and said electrodes through said anisotropic conductor after performing said dividing step.

2. A semiconductor device chip mounting method of mounting a semiconductor device chip having a plurality of projecting electrodes on a wiring board or wafer having electrodes respectively corresponding to said projecting electrodes of said semiconductor device chip, said semiconductor device chip mounting method comprising:
an insulator applying step of applying an insulator to a front side of said semiconductor device chip where said projecting electrodes are formed to fill a spacing between any adjacent ones of said projecting electrodes with said insulator;
a projecting electrode end exposing step of planarizing the front side of said semiconductor device chip covered with said insulator to expose end surfaces of said projecting electrodes after performing said insulator applying step; and
a mounting step of mounting said semiconductor device chip on said wiring board or said wafer with an anisotropic conductor interposed between said projecting electrodes of said semiconductor device chip and said electrodes of said wiring board or said wafer to thereby respectively connect said projecting electrodes and said electrodes through said anisotropic conductor after performing said projecting electrode end exposing step.

3. The semiconductor device chip mounting method according to claim 2, further comprising
an attaching step of attaching a plurality of semiconductor device chips to an adhesive tape after performing said insulator applying step, whereby said projecting electrode end exposing step is performed in a condition that said plurality of semiconductor device chips are attached to said adhesive tape.
